(19) United States
(12) Patent Application Publication
(10) Pub. No.: US 2025/0324876 A1
(43) Pub. Date: Oct. 16, 2025

(54) DISPLAY APPARATUS AND ELECTRONIC DEVICE

(71) Applicant: HKC CORPORATION LIMITED, Shenzhen (CN)

(72) Inventors: Zhihao WANG, Shenzhen (CN); Wenqin ZHAO, Shenzhen (CN); Kang LV, Shenzhen (CN); Yun LIN, Shenzhen (CN); Lidan YE, Shenzhen (CN)

(21) Appl. No.: 19/083,875

(22) Filed: Mar. 19, 2025

(30) Foreign Application Priority Data
Apr. 12, 2024 (CN) 202410457029.6

(51) Int. Cl. H10K 59/131

(52) U.S. Cl. CPC H10K 59/1315

(57) ABSTRACT

A display apparatus and an electronic device are provided. The display apparatus includes a circuit board, an anode layer, a cathode layer, a first signal line, and a second signal line. The circuit board is configured to provide a first signal and a second signal. The first signal line is configured to transmit the first signal. The first signal line is electrically connected to one of the anode layer and the cathode layer, and is connected to one end of the one of the anode layer and the cathode layer away from the circuit board. The second signal line is configured to transmit the second signal. The second signal line is electrically connected to the other of the anode layer and the cathode layer, and is connected to one end of the other of the anode layer and the cathode layer close to the circuit board.

### CROSS-REFERENCE TO RELATED APPLICATIONS

This application claims priority under 35 U.S.C. § 119(a) to Chinese Patent Application No. 202410457029.6, filed Apr. 12, 2024, the entire disclosure of which is incorporated herein by reference.

### TECHNICAL FIELD

The present disclosure relates to the field of display panel, and in particular, to a display apparatus and an electronic device.

### BACKGROUND

With the advancement of technology, organic light-emitting diode (OLED) technology has developed rapidly. However, larger-size OLED display apparatus have poor display effect during image display, and there is room for improvement.

### SUMMARY

In a first aspect, an embodiment of the disclosure provides a display apparatus. The display apparatus includes a circuit board, an anode layer, a cathode layer, a first signal line, and a second signal line. The circuit board is configured to provide a first signal and a second signal for driving an organic light-emitting diode (OLED) to emit light. The anode layer is disposed at one side of the circuit board and is spaced apart from the circuit board. The cathode layer and the anode layer are disposed at the same side of the circuit board, and the cathode layer and the anode layer are stacked. The first signal line is configured to transmit the first signal. The first signal line is electrically connected to one of the anode layer and the cathode layer, and is connected to one end of the one of the anode layer and the cathode layer away from the circuit board. The second signal line is configured to transmit the second signal. The second signal line is electrically connected to the other of the anode layer and the cathode layer, and is connected to one end of the other of the anode layer and the cathode layer close to the circuit board.

In a second aspect, an embodiment of the disclosure provides an electronic device, and the electronic device includes the display apparatus in the first aspect.

### BRIEF DESCRIPTION OF THE DRAWINGS

In order to describe technical solutions of embodiments of the disclosure more clearly, the following will give a brief introduction to the accompanying drawings used for describing the embodiments. Apparently, the accompanying drawings hereinafter described are some embodiments of the present disclosure. Based on these drawings, those of ordinary skill in the art can also obtain other drawings without creative effort.

FIG. 1 is a schematic view of an electronic device provided in an embodiment of the disclosure.

FIG. 2 is a schematic view of a display apparatus provided in the related technology.

FIG. 3 is a partial equivalent circuit diagram of the display apparatus provided in the related technology in FIG. 2.

FIG. 4 is a top view of a display apparatus provided in an embodiment of the disclosure.

FIG. 5 is a side view of the display apparatus provided in FIG. 4.

FIG. 6 is a schematic view of an organic light-emitting diode (OLED) and a peripheral circuit in the display apparatus illustrated in FIG. 4.

FIG. 7 is an equivalent circuit diagram of the display apparatus illustrated in FIG. 4.

FIG. 8 is a schematic view of the display apparatus illustrated in FIG. 4, viewed from another direction.

FIG. 9 is a schematic view of a display apparatus provided in another embodiment of the disclosure.

FIG. 10 is a sectional view of the display apparatus in FIG. 9 in an embodiment, taken along line I-I.

FIG. 11 is a sectional view of the display apparatus in FIG. 9 in another embodiment, taken along line I-I.

### REFERENCE SIGNS OF MAIN COMPONENTS

electronic device 1, display apparatus 10, housing 30, display region 10a, non-display region 10b, organic light-emitting diode 10c;
circuit board 110, anode layer 120, first side 121, second side 122, third side 123;
cathode layer 130, first signal line 140, first connection section 141, connection body section 142, second connection section 143, second signal line 150, third signal line 160, insulating medium layer 160a, insulating layer 170, through hole 170a, subpixel circuit 180, light-emitting layer 190;
first light-emitting unit D1, second light-emitting unit D2, third light-emitting unit D3.

### DETAILED DESCRIPTION

The following will clearly and completely illustrate technical solutions of embodiments of the disclosure with reference to the accompanying drawings of embodiments of the disclosure. Apparently, embodiments described herein are merely some embodiments, rather than all embodiments, of the disclosure. Based on the embodiments of the disclosure, all other embodiments obtained by those of ordinary skill in the art without creative effort shall fall within the protection scope of the disclosure.

The terms “first”, “second”, and the like in the description, claims of the present disclosure, and the above accompanying drawings are used for distinguishing different objects, rather than for describing a specific order. In addition, the terms “include”, “have”, and any variations thereof are intended to cover non-exclusive inclusions. For example, a process, method, system, product, or apparatus that includes a series of steps or units is not limited to the listed steps or units, but optionally further includes steps or units not listed, or optionally further includes other steps or units inherent to the process, method, product, or apparatus.

Reference to “embodiment” or “implementation” herein means that a particular feature, structure, or characteristic described in conjunction with the embodiment or implementation may be included in at least one embodiment of the present disclosure. The presence of the term at each place in the specification does not necessarily refer to the same embodiment, nor does it refer to a separate or alternative embodiment that is mutually exclusive of other embodiments. It may be understood by those skilled in the art, both explicitly and implicitly, that the embodiments described herein may be combined with other embodiments.

A display apparatus and an electronic device are provided in embodiments of the disclosure. The display apparatus and the electronic device provided in embodiments of the disclosure will be described in detail in the following.

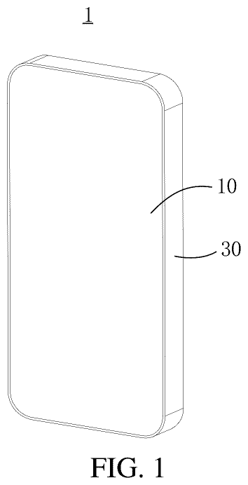

Reference is made to FIG. 1, which is a schematic view of an electronic device provided in an embodiment of the disclosure. An electronic device 1 may be, but is not limited to, a mobile phone, a tablet computer, or other devices with a display apparatus 10. The electronic device 1 includes the display apparatus 10. The display apparatus 10 is configured to implement the display function of the electronic device 1. In this embodiment, the display apparatus 10 is an organic light-emitting diode display (OLED) apparatus. In other words, light-emitting units in the display apparatus 10 are OLEDs.

In an embodiment, the electronic device 1 further includes a housing 30 for carrying the display apparatus 10. It is to be understood that in other embodiments, the electronic device 1 may not include the housing 30. Whether the electronic device 1 includes the housing 30 is not limited in embodiments of the disclosure.

It is to be noted that, examples and descriptions of the types of the electronic device 1 above are merely to introduce an application scenario of the display apparatus 10 and should not be understood as a limitation to the display apparatus 10 provided in embodiments of the disclosure.

To clearly illustrate the beneficial effects of the display apparatus 10 provided in embodiments of the disclosure, the display apparatus 10 provided in the related technology will be introduced before introducing the display apparatus 10 provided in embodiments of the disclosure.

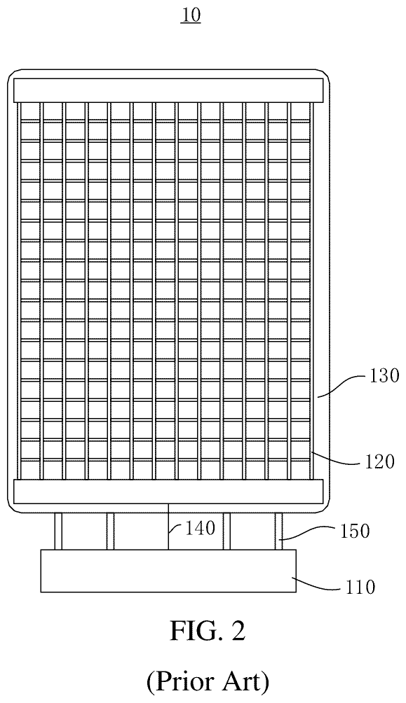

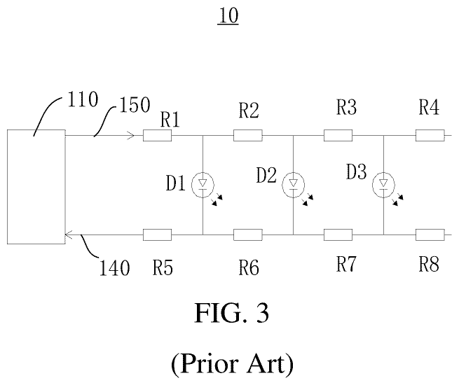

Reference is made to FIG. 2 and FIG. 3. FIG. 2 is a schematic view of a display apparatus provided in the related technology, and FIG. 3 is a partial equivalent circuit diagram of the display apparatus provided in the related technology in FIG. 2. The display apparatus 10 provided in the related technology includes a circuit board 110, a cathode layer 130, an anode layer 120, a first signal line 140, and a second signal line 150. The circuit board 110 is configured to generate a first signal and a second signal, and the first signal and the second signal cooperatively drive an OLED to emit light. The first signal line 140 is electrically connected to one end of the cathode layer 130 close to the circuit board 110 so as to transmit the first signal to the cathode layer 130. The second signal line 150 is electrically connected to one end of the anode layer 120 close to the circuit board 110 so as to transmit the second signal to the anode layer 120.

Typically, the circuit board 110 is disposed at one end of the display apparatus 10 (for example, the bottom end). In the case where the display apparatus 10 is a large-size device, the line impedance on the anode layer 120 increases as the distance between a position on the anode layer 120 and the circuit board 110 increases. Specifically, line resistance on a position on the anode layer 120 close to the circuit board 110 is relatively small, while resistance on a position on the anode layer 120 away from the circuit board 110 is relatively large. Thus, it will lead to a loss in the second signal in a position on the anode layer 120 away from the circuit board 110, resulting in brightness loss of an OLED away from the circuit board 110. This phenomenon is referred to as IR drop. The potential difference, or voltage drop, between two ends of a conducting wire during current flow is called IR drop.

Reference is made to FIG. 3, where OLEDs located in three rows in the display apparatus 10 perpendicular to a direction of the IR Drop are provided. These OLEDs located in three rows are sequentially named as first light-emitting unit D1, second light-emitting unit D2, and third light-emitting unit D3. The first light-emitting unit D1, the second light-emitting unit D2, and the third light-emitting unit D3 may be light-emitting units located in three adjacent rows. Alternatively, the first light-emitting unit D1, the second light-emitting unit D2, and the third light-emitting unit D3 may be light-emitting units located in three non-adjacent rows, with the distance between the first light-emitting unit D1 and the second light-emitting unit D2 being equal to the distance between the second light-emitting unit D2 and the third light-emitting unit D3. In other words, the first light-emitting unit D1, the second light-emitting unit D2, and the third light-emitting unit D3 are located in three rows spaced apart at equal intervals. The distance between the first light-emitting unit D1 and the circuit board 110 is a first length, the distance between the second light-emitting unit D2 and the circuit board 110 is a second length, and the distance between the third light-emitting unit D3 and the circuit board 110 is a third length, where the first length is smaller than the second length, and the second length is smaller than the third length. In other words, the first light-emitting unit D1 is the closest light-emitting unit to the circuit board 110, and the third light-emitting unit D3 is the farthest light-emitting unit from the circuit board 110.

The line resistance between the first light-emitting unit D1 and the second signal line 150 (also known as a VDD line resistance) is denoted by resistance R1. The line resistance between the first light-emitting unit D1 and the first signal line 140 (also known as a VSS line resistance) is denoted by resistance R5. The line resistance on the anode layer 120 between the second light-emitting unit D2 and the first light-emitting unit D1 (also known as the VDD line resistance) is denoted by resistance R2. The line resistance on the cathode layer 130 between the second light-emitting unit D2 and the first light-emitting unit D1 (also known as the VSS line resistance) is denoted by resistance R6. The line resistance on the anode layer 120 between the third light-emitting unit D3 and the second light-emitting unit D2 (also known as the VDD line resistance) is denoted by resistance R3. The line resistance on the cathode layer 130 between the third light-emitting unit D3 and the second light-emitting unit D2 (also known as the VSS line resistance) is denoted by resistance R7.

The first light-emitting unit D1, the second light-emitting unit D2, and the third light-emitting unit D3 may be light-emitting units located in three adjacent rows. Alternatively, the first light-emitting unit D1, the second light-emitting unit D2, and the third light-emitting unit D3 may be light-emitting units located in three non-adjacent rows, with the distance between the first light-emitting unit D1 and the second light-emitting unit D2 being equal to the distance between the second light-emitting unit D2 and the third light-emitting unit D3. Therefore, R2=R3, R6=R7.

The operating resistance of the first light-emitting unit D1, the operating resistance of the second light-emitting unit D2, and the operating resistance of the third light-emitting unit D3 are equal. For example, the operating resistance of the first light-emitting unit D1 refers to the equivalent resistance of the first light-emitting unit D1 in an operating state. The operating resistance of the first light-emitting unit D1 is denoted by R_{D1}, the operating resistance of the second light-emitting unit D2 is denoted by R_{D2}, and the operating resistance of the third light-emitting unit D3 is denoted by R_{D3}. That is, R_{D1}=R_{D2}=R_{D3}.

In the electrical circuit of the first light-emitting unit D1, the current flows through the second signal line 150 (also known as a VDD line) to the first light-emitting unit D1 and then to the first signal line 140 (also known as a VSS line). Correspondingly, in the electrical circuit of the second light-emitting unit D2, the current flows through the second signal line 150 (also known as the VDD line) to the second light-emitting unit D2 and then to the first signal line 140 (also known as the VSS line). Correspondingly, in the electrical circuit of the third light-emitting unit D3, the current flows through the second signal line 150 (also known as the VDD line) to the third light-emitting unit D3 and then to the first signal line 140 (also known as the VSS line).

Therefore, current I_{D1} of the first light-emitting unit D1, current I_{D2} of the second light-emitting unit D2, and current I_{D3} of the third light-emitting unit D3 satisfy:

I_{D1}=(VDD−VSS)/(R1+R5+R_{D1}) (1);

I_{D2}=(VDD−VSS)/(R1+R2+R5+R6+R_{D2}) (2);

I_{D3}=(VDD−VSS)/(R1+R2+R5+R6+R3+R7+R_{D3}) (3).

As can be seen, I_{D1}>I_{D2}>I_{D3}. That is, the current of the first light-emitting unit D1 is greater than the current of the second light-emitting unit D2, and the current of the second light-emitting unit D2 is greater than the current of the third light-emitting unit D3. Consequently, the brightness of the first light-emitting unit D1 is higher than the brightness of the second light-emitting unit D2, and the brightness of the second light-emitting unit D2 is higher than the brightness of the third light-emitting unit D3.

In conclusion, during the display of the display apparatus 10 provided in the related technology, the brightness of the light-emitting units away from the circuit board 110 is lower than the brightness of the light-emitting units close to the circuit board 110 due to the presence of IR drop, even if the circuit board 110 instructs all the light-emitting units in the display apparatus 10 to display the same brightness.

The display apparatus 10 provided in embodiments of the disclosure will be described in detail in the following.

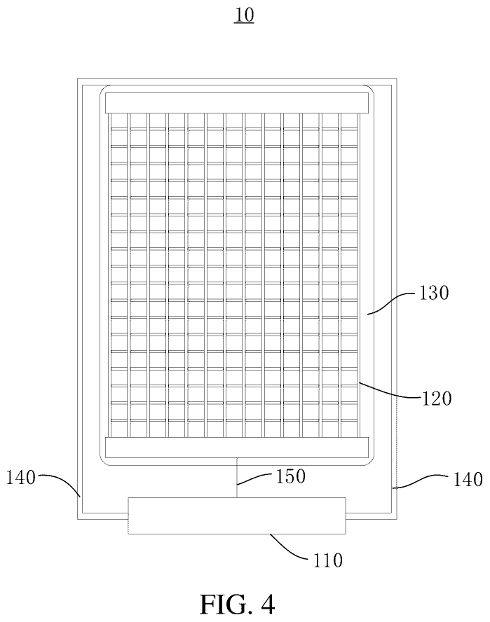

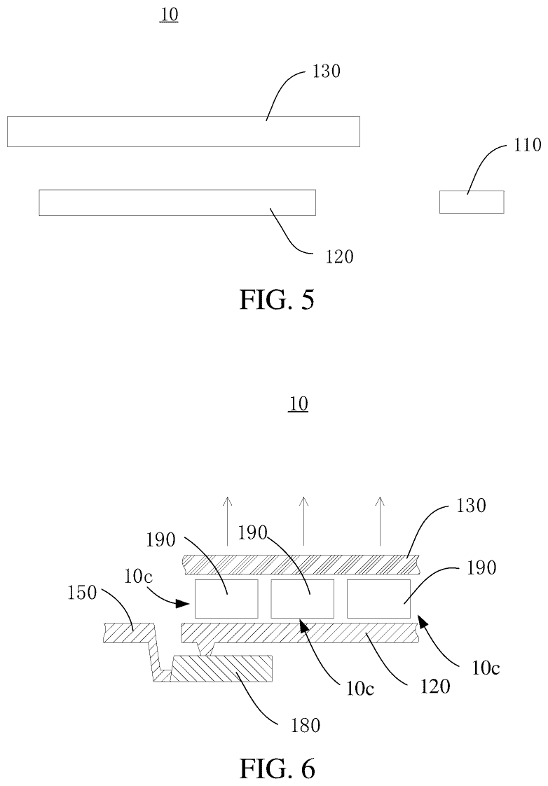

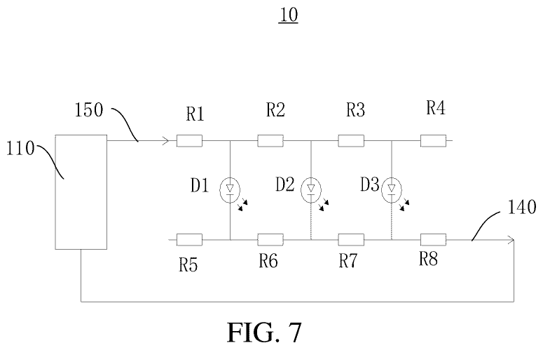

Reference is made to FIG. 4, FIG. 5, FIG. 6, and FIG. 7. FIG. 4 is a top view of a display apparatus provided in an embodiment of the disclosure. FIG. 5 is a side view of the display apparatus provided in FIG. 4. FIG. 6 is a schematic view of an OLED and a peripheral circuit in the display apparatus illustrated in FIG. 4. FIG. 7 is an equivalent circuit diagram of the display apparatus illustrated in FIG. 4. In order to clearly illustrate the stacking relationship between the anode layer 120 and the cathode layer 130, the first signal line 140 and the second signal line 150 are omitted in FIG. 5. The arrows in FIG. 6 indicate the light-emitting direction of an OLED 10c. The display apparatus 10 includes a circuit board 110, an anode layer 120, a cathode layer 130, a first signal line 140, and a second signal line 150. The circuit board 110 is configured to provide a first signal and a second signal for driving the OLED 10c to emit light. The anode layer 120 is disposed at one side of the circuit board 110 and is spaced apart from the circuit board 110. The cathode layer 130 and the anode layer 120 are disposed at the same side of the circuit board 110, and the cathode layer 130 and the anode layer 120 are stacked. The first signal line 140 is configured to transmit the first signal. The first signal line 140 is electrically connected to one of the anode layer 120 and the cathode layer 130, and is connected to one end of the one of the anode layer 120 and the cathode layer 130 away from the circuit board 110. The second signal line 150 is configured to transmit the second signal. The second signal line 150 is electrically connected to the other of the anode layer 120 and the cathode layer 130, and is connected to one end of the other of the anode layer 120 and the cathode layer 130 close to the circuit board 110.

The circuit board 110 may be, but is not limited to, a printed circuit board (PCB) 110. The circuit board 110 is configured to provide the first signal and the second signal, and the first signal and the second signal cooperatively drive the OLED 10c to emit light.

The anode layer 120 is of a mesh structure. The anode layer 120 may be transparent. The material of the anode layer 120 may be, but is not limited to, indium tin oxide (ITO). The cathode layer 130 is of a single-piece structure. In an embodiment, the cathode layer 130 may include silver and magnesium.

The anode layer 120 and the cathode layer 130 are both disposed at the same side of the circuit board 110. In the accompanying drawing, for illustrative purpose, the anode layer 120 and the cathode layer 130 both are disposed at the upper side of the circuit board 110. However, it is to be understood that this may not be construed as a limitation to the display apparatus 10 provided in the embodiment of the disclosure. The cathode layer 130 and the anode layer 120 are not arranged in the same layer. The cathode layer 130 and the anode layer 120 are stacked. Electrons are provided in the cathode layer 130, and holes are provided in the anode layer 120. The electron-hole recombination in a light-emitting layer 190 of the OLED 10c causes the OLED 10c to emit light.

In this embodiment, the first signal line 140 is electrically connected to the cathode layer 130, and the first signal line 140 is connected to one end of the cathode layer 130 away from the circuit board 110. The second signal line 150 is electrically connected to the anode layer 120, and the second signal line 150 is connected to one end of the anode layer 120 close to the circuit board 110. Correspondingly, the first signal transmitted by the first signal line 140 is a cathode signal, also known as a VSS signal; and the second signal transmitted by the second signal line 150 is an anode signal, also known as a VDD signal.

Reference is made to FIG. 6, where the display apparatus 10 includes the OLED 10c and a subpixel circuit 180. One pixel of the display apparatus 10 includes multiple OLEDs 10c of different colors. In the schematic diagram of this embodiment, for illustrative purpose, one pixel includes three OLEDs 10c of different colors. The three OLEDs 10c of different colors may include blue OLED 10c, red OLED 10c, and green OLED 10c. Each OLED 10c includes the light-emitting layer 190, which is sandwiched between the anode layer 120 and the cathode layer 130. The second signal line 150 is electrically connected to the anode layer 120 through the subpixel circuit 180. The first signal line 140 transmits the first signal to the cathode layer 130. When the subpixel circuit 180 is turned on, the second signal is transmitted to the anode layer 120, and the light-emitting layer 190 emits light under the combined action of the first signal and the second signal. In the schematic diagram of this embodiment, the three light-emitting layers 190 can emit different colors of light. For example, from the perspective illustrated in the diagram, the leftmost light-emitting layer 190 emits blue light, the middle light-emitting layer 190 emits red light, and the rightmost light-emitting layer 190 emits green light.

It is to be understood that, in other embodiments, the first signal line 140 is electrically connected to the anode layer 120, and the first signal line 140 is connected to the end of the anode layer 120 away from the circuit board 110; and the second signal line 150 is electrically connected to the cathode layer 130, and the second signal line 150 is connected to the end of the cathode layer 130 close to the circuit board 110. Correspondingly, the first signal transmitted by the first signal line 140 is an anode signal, also known as the VDD signal; the second signal transmitted by the second signal line 150 is a cathode signal, also known as the VSS signal.

Reference is made to FIG. 7, where OLEDs 10c located in three rows in the display apparatus 10 arranged in a direction from the circuit board 110 to the anode layer 120 are provided. These OLEDs 10c located in three rows are sequentially named as first light-emitting unit D1, second light-emitting unit D2, and third light-emitting unit D3. The first light-emitting unit D1, the second light-emitting unit D2, and the third light-emitting unit D3 may be light-emitting units located in three adjacent rows. Alternatively, the first light-emitting unit D1, the second light-emitting unit D2, and the third light-emitting unit D3 may be light-emitting units located in three non-adjacent rows, with the distance between the first light-emitting unit D1 and the second light-emitting unit D2 being equal to the distance between the second light-emitting unit D2 and the third light-emitting unit D3. In other words, the first light-emitting unit D1, the second light-emitting unit D2, and the third light-emitting unit D3 are located in three rows spaced apart at equal intervals. The distance between the first light-emitting unit D1 and the circuit board 110 is a first length, the distance between the second light-emitting unit D2 and the circuit board 110 is a second length, and the distance between the third light-emitting unit D3 and the circuit board 110 is a third length, where the first length is less than the second length, and the second length is less than the third length. In other words, the first light-emitting unit D1 is the closest light-emitting unit to the circuit board 110, and the third light-emitting unit D3 is the farthest light-emitting unit from the circuit board 110.

The line resistance between the first light-emitting unit D1 and the second signal line 150 (VDD signal line) is called as a VDD line resistance, which is denoted by R1. The line resistance between the first light-emitting unit D1 and the first signal line 140 (also known as a VSS line resistance) is denoted by resistance R5. The line resistance on the anode layer 120 between the second light-emitting unit D2 and the first light-emitting unit D1 (also known as the VDD line resistance) is denoted by resistance R2. The line resistance on the cathode layer 130 between the second light-emitting unit D2 and the first light-emitting unit D1 (also known as the VSS line resistance) is denoted by resistance R6. The line resistance on the anode layer 120 between the third light-emitting unit D3 and the second light-emitting unit D2 (also known as the VDD line resistance) is denoted by resistance R3. The line resistance on the cathode layer 130 between the third light-emitting unit D3 and the second light-emitting unit D2 (also known as the VSS line resistance) is denoted by resistance R7. The line resistance between the third light-emitting unit D3 and the first signal line 140 (VSS signal line) is denoted by resistance R8.

The first light-emitting unit D1, the second light-emitting unit D2, and the third light-emitting unit D3 may be light-emitting units located in three adjacent rows. Alternatively, the first light-emitting unit D1, the second light-emitting unit D2, and the third light-emitting unit D3 may be light-emitting units located in three non-adjacent rows, with the distance between the first light-emitting unit D1 and the second light-emitting unit D2 being equal to the distance between the second light-emitting unit D2 and the third light-emitting unit D3. Therefore, R2=R3, R6=R7.

The operating resistance of the first light-emitting unit D1, the operating resistance of the second light-emitting unit D2, and the operating resistance of the third light-emitting unit D3 are equal. For example, the operating resistance of the first light-emitting unit D1 refers to the equivalent resistance of the first light-emitting unit D1 in an operating state. The operating resistance of the first light-emitting unit D1 is denoted by R_{D1}, the operating resistance of the second light-emitting unit D2 is denoted by R_{D2}, and the operating resistance of the third light-emitting unit D3 is denoted by R_{D3}. That is, R_{D1}=R_{D2}=R_{D3}.

In the electrical circuit of the first light-emitting unit D1, the current flows through the second signal line 150 (also known as a VDD line) to the first light-emitting unit D1 and then to the first signal line 140 (also known as a VSS line). Correspondingly, in the electrical circuit of the second light-emitting unit D2, the current flows through the second signal line 150 (also known as the VDD line) to the second light-emitting unit D2 and then to the first signal line 140 (also known as the VSS line). Correspondingly, in the electrical circuit of the third light-emitting unit D3, the current flows through the second signal line 150 (also known as the VDD line) to the third light-emitting unit D3 and then to the first signal line 140 (also known as the VSS line).

Therefore, current I_{D01} of the first light-emitting unit D1, current I_{D02} of the second light-emitting unit D2, and current I_{D03} of the third light-emitting unit D3 satisfy:

I_{D01}=(VDD−VSS)/(R1+R6+R7+R8+R_{D1}) (1);

I_{D02}=(VDD−VSS)/(R1+R2+R7+R8+R_{D2}) (2);

I_{D03}=(VDD−VSS)/(R1+R2+R3+R8+R_{D3}) (3).

As can be seen, I_{D01}=I_{D02}=I_{D03}. That is, the current of the first light-emitting unit D1 is equal to the current of the second light-emitting unit D2, and the current of the first light-emitting unit D1 is equal to the current of the third light-emitting unit D3. Therefore, the brightness of the first light-emitting unit D1 is the same as the brightness of the second light-emitting unit D2, and the brightness of the first light-emitting unit D1 is the same as the brightness of the third light-emitting unit D3.

In conclusion, in the display apparatus 10 provided in embodiments of the disclosure, the first signal line 140 is configured to transmit the first signal. The first signal line 140 is electrically connected to one of the anode layer 120 and the cathode layer 130, and is connected to the end of the one of the anode layer 120 and the cathode layer 130 away from the circuit board 110. The second signal line 150 is configured to transmit the second signal. The second signal line 150 is electrically connected to the other of the anode layer 120 and the cathode layer 130, and is connected to the end of the other of the anode layer 120 and the cathode layer 130 close to the circuit board 110. In this way, currents that flow in light-emitting units located in different rows in the display apparatus 10, from the circuit board 110 to the anode layer 120, are equal or substantially equal, so that light-emitting units located in different rows have the same or substantially the same display brightness. Therefore, the display apparatus 10 provided in embodiments of the disclosure has good display effect.

In this embodiment, the first signal line 140 is electrically connected to the end of the cathode layer 130 away from the circuit board 110. The second signal line 150 is electrically connected to the end of the anode layer 120 close to the circuit board 110.

The first signal line 140 is electrically connected to the cathode layer 130, and the second signal line 150 is electrically connected to the anode layer 120. The first signal loaded on the first signal line 140 is a VSS signal, and the second signal loaded on the second signal line 150 is a VDD signal. The voltage of the VSS signal is 0V, and the VDD signal is usually a signal with positive voltage. The first signal line 140 is electrically connected to the end of the cathode layer 130 away from the circuit board 110, and the second signal line 150 is electrically connected to the end of the anode layer 120 close to the circuit board 110. On one hand, this configuration allows currents that flow in light-emitting units located in different rows in the display apparatus 10 in the direction from the circuit board 110 to the anode layer 120 to be equal or substantially equal, so that light-emitting units located in different rows have the same or substantially the same display brightness; on the other hand, since the VDD signal can be transmitted to the anode layer 120 in a short distance, the loss of the VDD signal may be reduced, thereby enabling the brightness of light-emitting units located in different rows to be higher for a fixed voltage of the VDD signal.

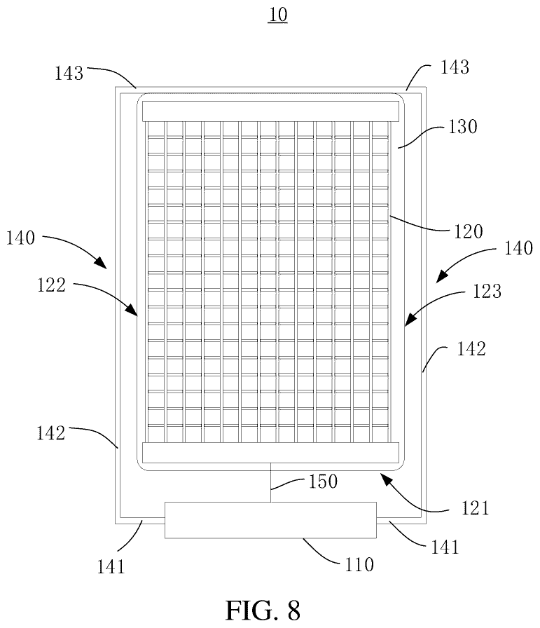

Reference is further made to FIG. 8, which is a schematic view of the display apparatus illustrated in FIG. 4, viewed from another direction. The cathode layer 130 includes a first side 121, a second side 122, and a third side 123. The first side 121 is one side of the cathode layer 130 facing the circuit board 110. The second side 122 is connected to the first side 121 in a bent manner. The third side 123 is connected to the first side 121 in a bent manner, the third side 123 is spaced apart from the second side 122, and the third side 123 and the second side 122 are disposed at the same side of the first side 121. The first signal line 140 is implemented as two first signal lines 140, where a part of one of the two first signal lines 140 is located at one side of the second side 122 away from the third side 123, and a part of the other of the two first signal lines 140 is located at one side of the third side 123 away from the second side 122.

In this embodiment, the first side 121 is the bottom side, the second side 122 is the left side, and the third side 123 is the right side. It is to be understood that, in other embodiments, different placement angles of the display apparatus 10 will lead to different positions of the first side 121, the second side 122, and the third side 123.

A part of one of the two first signal lines 140 is located at the side of the second side 122 away from the third side 123, and a part of the other of the two first signal lines 140 is located at the side of the third side 123 away from the second side 122. In other words, the two first signal lines 140 are disposed at opposite sides of the cathode layer 130. By disposing the two first signal lines 140 according to the above-mentioned layout, regions of the display apparatus 10 corresponding to the two first signal lines 140 will be the same or similar in size, thereby facilitating the encapsulation of the display apparatus 10.

Reference is further made to FIG. 8. The first signal line 140 includes a first connection section 141, a connection body section 142, and a second connection section 143 connected in sequence. First connection sections 141 of the two first signal lines 140 are both electrically connected to the circuit board 110. A connection body section 142 of one of the two first signal lines 140 is located at the side of the second side 122 away from the third side 123, and a connection body section 142 of the other of the two first signal lines 140 is located at the side of the third side 123 away from the second side 122. Second connection sections 143 of the two first signal lines 140 are both electrically connected to the cathode layer 130.

One end of the connection body section 142 is connected to one end of the first connection section 141 in a bent manner, and the other end of the connection body section 142 is connected to one end of the second connection section 143 in a bent manner. The connection body section 142 of one of the two first signal lines 140 is located at the side of the second side 122 away from the third side 123, and the connection body section 142 of the other of the two first signal lines 140 is located at the side of the third side 123 away from the second side 122. In other words, the connection body sections 142 of the two first signal lines 140 are disposed at opposite sides of the cathode layer 130. With the aid of such arrangement of the two first signal lines 140, regions of the display apparatus 10 corresponding to the connection body sections 142 of the two first signal lines 140 will be the same or similar in size, thereby facilitating the encapsulation of the display apparatus 10.

In an embodiment, the size of the display apparatus 10 ranges from 4 inches to 7 inches, each part of the connection body section 142 is equal in film thickness, and the film thickness of the connection body section 142 ranges from 22 angstroms to 88 angstroms.

The size of the display apparatus 10 may be, but is not limited to, 4 inches, 5 inches, 6 inches, or 7 inches. The film thickness of the connection body section 142 may be, but is not limited to, 22 angstroms, 30 angstroms, 40 angstroms, 50 angstroms, 60 angstroms, 70 angstroms, 80 angstroms, 85 angstroms, or 88 angstroms, where 1 angstrom=0.1 nanometers (nm).

For a display apparatus 10 of a certain size, in the case where the first signal and the second signal remain unchanged and the material of the connection body section 142 and the length of the connection body section 142 remain unchanged, a smaller film thickness of the connection body section 142 leads to a greater resistance of the connection body section 142, and correspondingly, a lower brightness of the display apparatus 10; a greater thickness of the connection body section 142 leads to a lower resistance of the connection body section 142, and correspondingly, a higher brightness of the display apparatus 10. For example, for a 4-inch display apparatus 10, in the case where the first signal and the second signal remain unchanged and the material of the connection body section 142 and the length of the connection body section 142 remain unchanged, when the film thickness of the connection body section 142 is 22 angstroms, the resistance is relatively large, and the brightness of the display apparatus 10 is relatively low; and correspondingly, when the thickness of the connection body section 142 is 88 angstroms, the resistance is relatively small, and the brightness of the display apparatus 10 is relatively high.

In this embodiment, the size of the display apparatus 10 ranges from 4 inches to 7 inches, each part of the connection body section 142 is equal in film thickness, and the film thickness of the connection body section 142 ranges from 22 angstroms to 88 angstroms. In this way, the overall resistance of the connection body section 142 is relatively small, resulting in a relatively high display brightness of the display apparatus 10 with a size ranging from 4 inches to 7 inches.

Further, in conjunction with any of the previous embodiments, the width of the connection body section 142 is greater than 7 micrometers.

In an embodiment, the width of the connection body section 142 ranges from 7 micrometers to 15 micrometers. In another embodiment, the width of the connection body section 142 ranges from 7 micrometers to 10 micrometers.

For example, the width of the connection body section 142 may be, but is not limited to, 7 micrometers, 8 micrometers, 9 micrometers, 10 micrometers, etc.

In the case where the material of the connection body section 142 and the film thickness range of the connection body section 142 remain unchanged, a greater width of the connection body section 142 leads to a lower resistance per unit length of the connection body section 142, resulting in the display apparatus 10 having a relatively high display brightness.

In addition, in the case where the sheet resistance of the material of the first signal line 140 provided in the embodiment of the disclosure remains unchanged, by adjusting the film thickness and the width of the first signal line 140, mainly by adjusting the film thickness and width of the connection body section 142 of the first signal line 140, the resistances of R5 to R8 in the display apparatus 10 provided in the embodiment of the disclosure can be controlled to be the same as the resistances of R1 to R4 respectively. Specifically, in an embodiment, in the case where the sheet resistance of the material of the first signal line 140 remains unchanged, by adjusting the film thickness and the width of the first signal line 140, mainly by adjusting the film thickness and width of the connection body section 142 of the first signal line 140, R5=R1, R6=R2, R7=R3, R8=R4. In this way, for the display apparatus 10 provided in the embodiment of the disclosure, light-emitting units located in different rows in the direction from the circuit board 110 to the anode layer 120 have the same or substantially the same display brightness in the case where the first signal and the second signal remain unchanged.

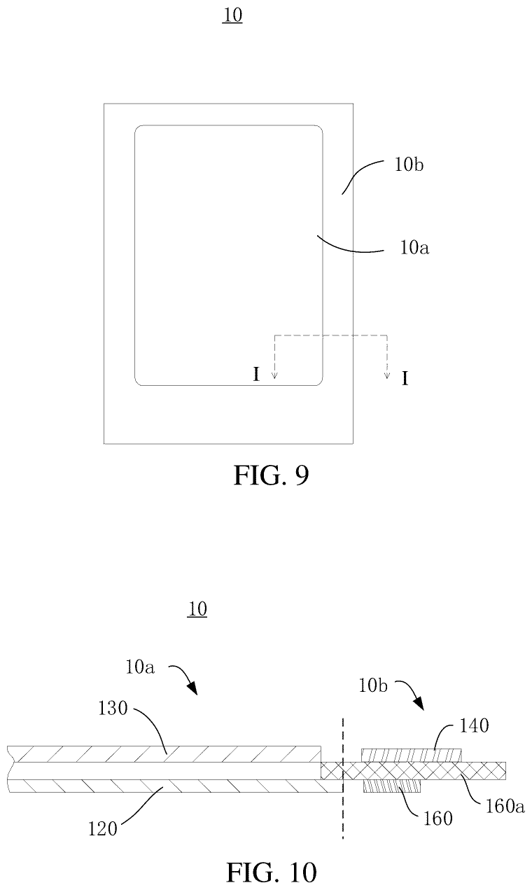

Reference is made to FIG. 9 and FIG. 10. FIG. 9 is a schematic view of a display apparatus provided in another embodiment of the disclosure. FIG. 10 is a sectional view of the display apparatus in FIG. 9 in an embodiment, taken along line I-I. In this embodiment, the display apparatus 10 further includes one or more third signal lines 160. The display apparatus 10 includes a display region 10a and a non-display region 10b. The anode layer 120 and the cathode layer 130 are both located in the display region 10a. The non-display region 10b is disposed at a periphery of the display region 10a, and at least part of the one or more third signal lines 160 is located in the non-display region 10b. At least part of the first signal line 140 is located in the non-display region 10b, and the at least part of the first signal line 140 located in the non-display region 10b and the at least part of the one or more third signal lines 160 located in the non-display region 10b are stacked.

The display region 10a of the display apparatus 10 is a region for image display, and the non-display region 10b is a region that is unable to display image. The non-display region 10b is disposed at the periphery of the display region 10a. For example, the non-display region 10b may be located at the side of the second side 122 away from the third side 123 and located at the side of the third side 123 away from the second side 122. The non-display region 10b is used to cover at least part of the first signal line 140 and at least part of the one or more third signal lines 160.

In this embodiment, the anode layer 120 and the cathode layer 130 are stacked in a preset direction. The at least part of the first signal line 140 located in the non-display region 10b and the at least part of the one or more third signal lines 160 located in the non-display region 10b are stacked, which may be that the at least part of the first signal line 140 located in the non-display region 10b and the at least part of the one or more third signal lines 160 located in the non-display region 10b are stacked in the preset direction. An insulating medium layer 160a may be disposed between the first signal line 140 and the one or more third signal lines 160. In this way, the size of the display region 10a of the display apparatus 10 may be relatively small, which helps to produce the display apparatus 10 with a narrow frame.

In an embodiment, the one or more third signal lines 160 include one or more of a clock signals (CK) line, a gate high voltage (VGH) line, a gate low voltage (VGL) line, a touch signal receiving line, or a touch signal transmitting line.

The one or more third signal lines 160 include one or more of a CK line, a VGH line, a VGL line, a touch signal receiving line, or a touch signal transmitting line. The at least part of the one or more third signal lines 160 is located in the non-display region 10b, the at least part of the first signal line 140 is located in the non-display region 10b, and the at least part of the first signal line 140 located in the non-display region 10b and the at least part of the one or more third signal lines 160 located in the non-display region 10b are stacked. In this way, the first signal line 140 and the third signal line 160 configured to drive and coordinate the operation of the display apparatus 10 are at least partially stacked, to make the size of the display region 10a of the display apparatus 10 relatively small, which helps to produce the display apparatus 10 with a narrow frame.

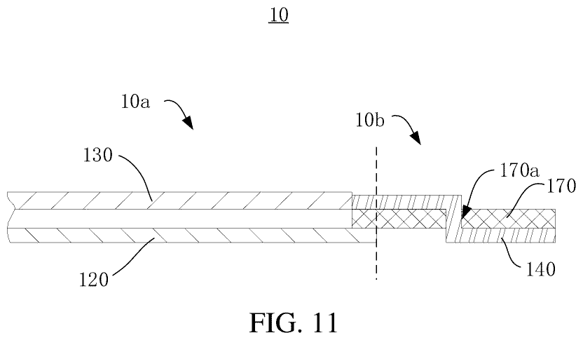

Further, reference is made to FIG. 11, which is a sectional view of the display apparatus in FIG. 9 in another embodiment, taken along line I-I. The first signal line 140 and the cathode layer 130 are arranged in different layers. The display apparatus 10 includes an insulating layer 170. The insulating layer 170 is located between the first signal line 140 and the cathode layer 130, and the insulating layer 170 defines a through hole 170a. The first signal line 140 is electrically connected to the cathode layer 130 through the through hole 170a.

The insulating layer 170 is located between the first signal line 140 and the cathode layer 130, and the insulating layer 170 defines the through hole 170a, which penetrates two opposite surfaces of the insulating layer 170.

In this embodiment, the first signal line 140 is located in the non-display region 10b, the insulating layer 170 is located between the first signal line 140 and the cathode layer 130, and the insulating layer 170 defines the through hole 170a. The first signal line 140 is electrically connected to the cathode layer 130 through the through hole 170a. In this way, the region occupied by the first signal line 140 in the non-display region 10b may be reduced, and the distance between the orthographic projection of the first signal line 140 on the plane where the cathode layer 130 is located and the region where the cathode layer 130 is located may be set to be relatively small, or even adjacent to each other, thereby further enabling the display apparatus 10 to have a narrow frame.

Although the embodiments of the present disclosure have been illustrated and described above, it can be understood that the above embodiments are illustrative and cannot be understood as limitations on the present disclosure. Those skilled in the art can make changes, modifications, replacements, and variations for the above embodiments within the scope of the present disclosure, and these improvements and modifications are also considered to fall into the protection scope of the present disclosure.

What is claimed is:

1. A display apparatus, comprising:
a circuit board, wherein the circuit board is configured to provide a first signal and a second signal for driving an organic light-emitting diode (OLED) to emit light;
an anode layer, wherein the anode layer is disposed at one side of the circuit board and is spaced apart from the circuit board;
a cathode layer, wherein the cathode layer and the anode layer are disposed at a same side of the circuit board, and the cathode layer and the anode layer are stacked;
a first signal line, wherein the first signal line is configured to transmit the first signal, and the first signal line is electrically connected to one of the anode layer and the cathode layer, and is connected to one end of the one of the anode layer and the cathode layer away from the circuit board; and
a second signal line, wherein the second signal line is configured to transmit the second signal, and the second signal line is electrically connected to the other of the anode layer and the cathode layer, and is connected to one end of the other of the anode layer and the cathode layer close to the circuit board.

2. The display apparatus of claim 1, wherein the first signal line is electrically connected to one end of the cathode layer away from the circuit board; and
the second signal line is electrically connected to one end of the anode layer close to the circuit board.

3. The display apparatus of claim 2, wherein the cathode layer comprises:
a first side, wherein the first side is one side of the cathode layer facing the circuit board;
a second side, wherein the second side is connected to the first side in a bent manner; and
a third side, wherein the third side is connected to the first side in a bent manner, the third side is spaced apart from the second side, and the third side and the second side are disposed at a same side of the first side;
wherein the first signal line is implemented as two first signal lines, a part of one of the two first signal lines is located at one side of the second side away from the third side, and a part of the other of the two first signal lines is located at one side of the third side away from the second side.

4. The display apparatus of claim 3, wherein the first signal line comprises a first connection section, a connection body section, and a second connection section connected in sequence;
first connection sections of the two first signal lines are both electrically connected to the circuit board;
a connection body section of one of the two first signal lines is located at the side of the second side away from the third side, and a connection body section of the other of the two first signal lines is located at the side of the third side away from the second side; and
second connection sections of the two first signal lines are both electrically connected to the cathode layer.

5. The display apparatus of claim 4, wherein a size of the display apparatus ranges from 4 inches to 7 inches, each part of the connection body section is equal in film thickness, and the film thickness of the connection body section ranges from 22 angstroms to 88 angstroms.

6. The display apparatus of claim 4, wherein a width of the connection body section is greater than 7 micrometers.

7. The display apparatus of claim 4, further comprising one or more third signal lines; wherein the display apparatus comprises:
a display region, wherein the anode layer and the cathode layer both are located in the display region; and
a non-display region, wherein the non-display region is disposed at a periphery of the display region, and at least part of the one or more third signal lines is located in the non-display region; at least part of the first signal line is located in the non-display region, and the at least part of the first signal line located in the non-display region and the at least part of the one or more third signal lines located in the non-display region are stacked.

8. The display apparatus of claim 7, wherein the one or more third signal lines comprise:
one or more of a clock signals (CK) line, a gate high voltage (VGH) line, a gate low voltage (VGL) line, a touch signal receiving line, or a touch signal transmitting line.

9. The display apparatus of claim 7, wherein the first signal line and the cathode layer are arranged in different layers, and the display apparatus comprises:
an insulating layer, wherein the insulating layer is located between the first signal line and the cathode layer, the insulating layer defines a through hole, and the first signal line is electrically connected to the cathode layer through the through hole.

10. An electronic device, wherein the electronic device comprises a display apparatus, wherein the display apparatus comprises:
a circuit board, wherein the circuit board is configured to provide a first signal and a second signal for driving an OLED to emit light;
an anode layer, wherein the anode layer is disposed at one side of the circuit board and is spaced apart from the circuit board;
a cathode layer, wherein the cathode layer and the anode layer are disposed at a same side of the circuit board, and the cathode layer and the anode layer are stacked;
a first signal line, wherein the first signal line is configured to transmit the first signal, and the first signal line is electrically connected to one of the anode layer and the cathode layer, and is connected to one end of the one of the anode layer and the cathode layer away from the circuit board; and
a second signal line, wherein the second signal line is configured to transmit the second signal, and the second signal line is electrically connected to the other of the anode layer and the cathode layer, and is connected to one end of the other of the anode layer and the cathode layer close to the circuit board.

11. The electronic device of claim 10, wherein the first signal line is electrically connected to one end of the cathode layer away from the circuit board; and
the second signal line is electrically connected to one end of the anode layer close to the circuit board.

12. The electronic device of claim 11, wherein the cathode layer comprises:
a first side, wherein the first side is one side of the cathode layer facing the circuit board;
a second side, wherein the second side is connected to the first side in a bent manner; and
a third side, wherein the third side is connected to the first side in a bent manner, the third side is spaced apart from the second side, and the third side and the second side are disposed at a same side of the first side;
wherein the first signal line is implemented as two first signal lines, a part of one of the two first signal lines is located at one side of the second side away from the third side, and a part of the other of the two first signal lines is located at one side of the third side away from the second side.

13. The electronic device of claim 12, wherein the first signal line comprises a first connection section, a connection body section, and a second connection section connected in sequence;
first connection sections of the two first signal lines are both electrically connected to the circuit board;
a connection body section of one of the two first signal lines is located at the side of the second side away from the third side, and a connection body section of the other of the two first signal lines is located at the side of the third side away from the second side; and
second connection sections of the two first signal lines are both electrically connected to the cathode layer.

14. The electronic device of claim 13, wherein a size of the display apparatus ranges from 4 inches to 7 inches, each part of the connection body section is equal in film thickness, and the film thickness of the connection body section ranges from 22 angstroms to 88 angstroms.

15. The electronic device of claim 13, wherein a width of the connection body section is greater than 7 micrometers.

16. The electronic device of claim 13, further comprising one or more third signal lines; wherein the display apparatus comprises:
a display region, wherein the anode layer and the cathode layer both are located in the display region; and
a non-display region, wherein the non-display region is disposed at a periphery of the display region, and at least part of the one or more third signal lines is located in the non-display region; at least part of the first signal line is located in the non-display region, and the at least part of the first signal line located in the non-display region and the at least part of the one or more third signal lines located in the non-display region are stacked.

17. The electronic device of claim 16, wherein the one or more third signal lines comprise:
one or more of a CK line, a VGH line, a VGL line, a touch signal receiving line, or a touch signal transmitting line.

18. The electronic device of claim 16, wherein the first signal line and the cathode layer are arranged in different layers, and the display apparatus comprises:
an insulating layer, wherein the insulating layer is located between the first signal line and the cathode layer, the insulating layer defines a through hole, and the first signal line is electrically connected to the cathode layer through the through hole.
